(19) United States
(12) Patent Application Publication
(10) Pub. No.: US 2025/0183903 A1
(43) Pub. Date: Jun. 5, 2025

(54) QUADRATURE HARMONIC SELF-OSCILLATING MIXER FOR MULTI-FUNCTION WIRELESS COMMUNICATION AND SENSING SYSTEMS AND METHODS THEREOF

(71) Applicant: Huawei Technologies Canada Co., Ltd., Kanata (CA)

(72) Inventors: Pascal Burasa, Cote Saint-Luc (CA); Yasser Bigdeli, Montreal (CA); Ke Wu, Montreal (CA)

(21) Appl. No.: 19/049,167

(22) Filed: Feb. 10, 2025

Related U.S. Application Data
(63) Continuation of application No. PCT/CA2022/051229, filed on Aug. 11, 2022.

(51) Int. Cl. H03L 7/24; H03B 5/12; H03D 7/12; H03D 7/14

(52) U.S. Cl. CPC H03L 7/24; H03B 5/1243; H03D 7/125; H03D 7/1441

(57) ABSTRACT

A module for modulation and demodulation using two substantially identical self-oscillating mixers (SOMs) injection-locked at a coupling frequency, providing a simple compact, low power, highly efficient receiver, transmitter or transceiver. The module suitable for quadrature amplitude-modulation where the coupling frequency is the second harmonic frequency of the SOMs and the SOMs oscillate 180 degrees out of phase relative to one another. Use of carrier frequencies at a fundamental harmonic frequency or odd multiples thereof provide high isolation between the SOMs at the carrier frequency. A method for modulation and demodulation includes injection-locking the two SOMs at a coupling frequency.

### CROSS-REFERENCE TO RELATED APPLICATION

The present application is a continuation of Patent Cooperation Treaty Application Serial No. PCT/CA2022/051229, entitled “QUADRATURE HARMONIC SELF-OSCILLATING MIXER FOR MULTI-FUNCTION WIRELESS COMMUNICATION AND SENSING SYSTEMS AND METHODS THEREOF,” filed on Aug. 11, 2022, the entirety of which is incorporated by reference herein.

### TECHNICAL FIELD

The present disclosure relates generally to wireless signal transmitters and/or receivers, and in particular, to wireless signal transmitters and/or receivers having quadrature harmonic self-oscillating mixers.

### BACKGROUND

A rapidly evolving information society has resulted in increased technological demands including for integrating multiple wireless functionalities, such as sensing, imaging, locating, powering, and communication, into single, multi-purpose devices to address multiple needs, for example, requirements for higher resolution and sensitivity in sensing applications and improved devices and improved techniques involving high spectral efficiency modulation in high performance wireless communications applications, such as quadrature-phase modulation (QAM). Low-power and compact transceiver cores comprising quadrature-phase modulation and demodulation capabilities may be highly desirable to such ends.

The use of discrete circuit components to perform different operation results in a system having high power consumption and developmental complexity, which thereby may not be optimal for use in portable, battery-powered and/or wireless powered devices. Active components within a receiver and transmitter chain, especially local oscillators, mixers, and amplifiers consume power and introduce noise and interference. In a large-scale transceiver array, this issue is more significant, where multiple mixers and local oscillators are required in order to enable multi-functionalities.

Current-reuse receivers are utilized in applications such as global positioning systems (GPS), ZIGBEE® (ZIGBEE is a registered trademark of ZigBee Alliance Corp., San Ramon, CA, USA), and wireless sensor networks. However, current-reuse receivers face issues respecting limited operable frequency ranges and operating efficiencies. Devices using self-oscillating mixers (SOMs) are also used in wireless technologies but are application specific and are not readily adapted for use in multi-function systems.

### SUMMARY

The present disclosure provides modules, systems and methods for transmitting and receiving signals, wherein a module includes two SOMs injection-locked at a coupling frequency along with passive circuits to provide receivers, transmitters, and transceivers, including involving modulation techniques such as quadrature-phase modulation (QAM). In embodiments disclosed herein, the SOMs are injection-locked at a second harmonic frequency with the SOMs oscillating 180 degrees out of phase relative to one another making the module suitable for high spectral efficiency modulation applications (for example amplitude-shift keying, phase-shift keying and QAM applications) and providing a simple compact, low power, highly efficient receiver, transmitter, or transceiver suitable for multi-function systems and large arrays. In embodiments disclosed herein, the module operates at a carrier signal of a fundamental harmonic of the SOMs or an odd multiple thereof thereby providing high isolation between the SOMs at the carrier frequency. In embodiments disclosed herein, the ability to optionally add an amplifier stage for increased performance with an inherently compact structure suitable for modules for millimeter-wave and terahertz frequencies.

According to one aspect of this disclosure, there is provided a module including a first port, a first SOM, and a second SOM. The first port for being energized by a first modulated signal. The first SOM for transformation between the first signal and a first component of a second signal, the first SOM including a second port and a third port. The second SOM for transformation between the first signal and a second component of the second signal, the second SOM having a fourth port and a fifth port. The first and second SOMs have a substantially same fundamental frequency, the first and second SOMs are configured to be injection-locked at a coupling frequency, the second and fourth ports are connected to the first port, and the third and fifth ports are configured to be energized by the first and second components of the second signal, respectively.

In embodiments disclosed herein, the coupling frequency is substantially equal to a multiple of the fundamental frequency.

In embodiments disclosed herein, the coupling frequency is substantially equal to a second harmonic frequency of the first and second SOMs.

In embodiments disclosed herein, the second SOM is configured to oscillate about 180 degrees out of phase with the first SOM, the first signal is quadrature amplitude-modulated, the first component of the second signal is a demodulated in-phase component of the first signal, and the second component of the second signal is a demodulated quadrature component of the first signal.

In embodiment disclosed herein, the first signal has a carrier frequency substantially equal to a multiple of the fundamental frequency.

In embodiments disclosed herein, the first signal has a carrier frequency substantially equal to the fundamental frequency or a third harmonic frequency of the first and second SOMs.

In embodiments disclosed herein, the first port is for being energized by and receiving the first signal, the first and second SOMs are for demodulating the first signal to the first and second components of the second signal, and the third and fifth ports are for outputting the first and second components of the second signal, respectively.

In embodiments disclosed herein, the first port is connected to the second and fourth ports via a power divider.

In embodiments disclosed herein, the first port is coupled to a low noise amplifier.

In embodiments disclosed herein, the first port is for being energized by and transmitting the first signal, the first and second SOMs are for modulating the second signal to the first signal, and the third and fifth ports are for inputting the first and second components of the second signal, respectively.

In embodiments disclosed herein, the first port is connected to the second and fourth ports via a power combiner.

In embodiments disclosed herein, the first port is coupled to an amplifier.

According to one aspect of this disclosure, there is provided a method including injection-locking a first SOM and a second SOM at a coupling frequency, where the first and second SOMs have a substantially same fundamental frequency, the first and second SOMs are oscillating at a carrier frequency, the first SOM is for transforming between a first signal and a first component of a second signal, and the second SOM is for transforming between the first signal and a second component of the second signal.

### BRIEF DESCRIPTION OF THE DRAWINGS

For a more complete understanding of the disclosure, reference is made to the following description and accompanying drawings, in which:

FIG. 1A is a schematic of a prior-art structure of a single stage current-reuse receiver;

FIG. 1B is a schematic of a prior-art structure of a SOM;

FIG. 1C is a schematic of a prior-art zero-intermediate-frequency self-oscillating mixer topology;

FIG. 1D is a schematic illustrating prior-art polarization diversity of a system for quadrature phase modulation and demodulation;

FIG. 2A is a schematic of a prior-art structure of a current-reuse transmitter;

FIG. 2B is a schematic of a prior-art structure of a SOM;

FIG. 3 is a schematic illustrating an embodiment of a module for modulation and demodulation;

FIG. 4A is a graph showing time domain output for a quadrature harmonic self-oscillating mixer (QHSOM), representing quadrature phase difference between I and Q oscillators and a harmonic oscillator;

FIG. 4B is a graph showing frequency domain output for a QHSOM, representing quadrature phase difference between I and Q oscillators and a harmonic oscillator;

FIG. 5A is a graph showing crosstalk for radio frequency input around a first fundamental harmonic frequency of an SOM;

FIG. 5B is a graph showing crosstalk for radio frequency input around a third harmonic frequency of an SOM;

FIG. 6A is a schematic of an embodiment of a module configured as a receiver;

FIG. 6B is a schematic of an embodiment of a coupling connection of a module;

FIG. 6C is a schematic of an embodiment of a power divider of a module;

FIG. 6D is a schematic of an embodiment of a diplexer of a module;

FIG. 7A and FIG. 7B are graphs showing s-parameters of the coupling connection of FIG. 6B around a second harmonic frequency;

FIG. 7C and FIG. 7D are graphs showing s-parameters of the diplexer of FIG. 6D around a second harmonic frequency;

FIG. 8 is a schematic of the module of FIG. 6A comprising a low noise amplifier;

FIG. 9A is a schematic of an embodiment of a module configured as a transmitter;

FIG. 9B is a schematic of the module of FIG. 9A comprising an amplifier;

FIG. 10 is a flowchart of a method for receiving and demodulating a modulated signal; and

FIG. 11 is a flowchart of a method for modulating and transmitting a modulated signal.

### DETAILED DESCRIPTION

Although embodiments have been described above with reference to the accompanying drawings, those of skill in the art will appreciate that variations and modifications may be made without departing from the scope thereof as defined by the appended claims.

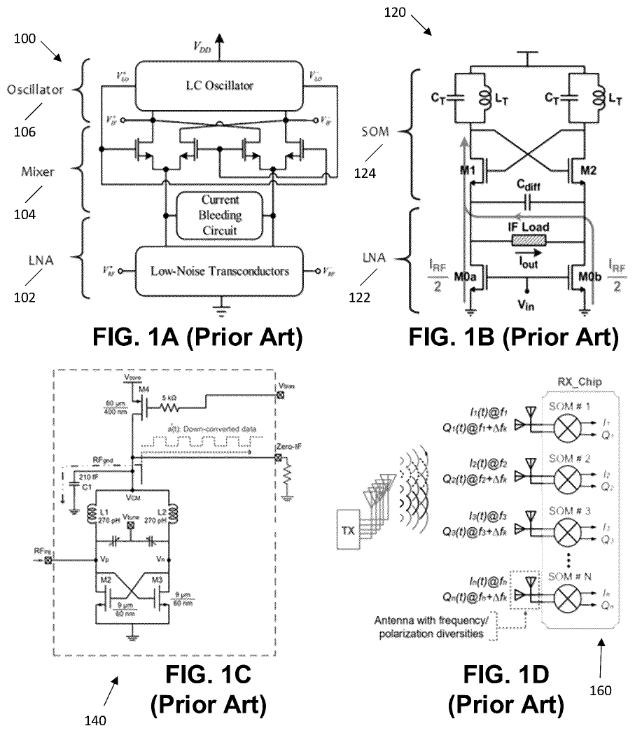

FIG. 1A illustrates the structure of a prior-art single-stage current-reuse receiver 100 comprising a first portion 102, a second portion 104, and a third portion 106. The receiver 100 is constructed from a cascoding receive chain and re-uses current from a power supply. The first portion 102 generally comprises a low-noise amplifier (LNA) followed by the second portion 104 comprising a mixer and the third portion 106 comprising an oscillator, wherein the first portion 102, the second portion 104 and the third portion 106 all share a common current source.

Although the configuration of this receiver 100 can result in a compact and low power consumption receiver unit, it has some limitations. The first issue with the receiver 100 is scalability. By cascoding portions, each portion uses and requires a portion of a power supply voltage, which results in overall performance degradation of each portion. At microwave frequencies (generally in the range of hundreds of MHz to tens of GHz), transistors are highly efficient, and even operating at low voltages, good performance (such as low noise, high gain, good power efficiency, and/or the like) can be achieved. However, when scaling at millimeter-wave (about 30 GHz to 300 GHz) and terahertz (about 0.1THz to 10THz) bands, cascoding portions in current-reuse topologies cannot be used due to lower operating efficiency of transistors and lower available power supply voltage (restricted by compatible technologies in this frequency range). Due to strong transistor parasitics at the millimeter-wave and terahertz bands, low noise amplification is not achievable and each transistor becomes a source of noise. Therefore, despite the characteristic of compactness of current-reuse receiver topology at microwave bands, they are not ideal to be used in larger scale applications. Further, current-reuse receiver topologies provide limited performance features, lacking capabilities such as phase extraction and image rejection, which are required for enabling high sensing and communication performance, respectively. Therefore, current-reuse receiver topologies may not be suitable for multi-function systems.

Devices incorporating self-oscillating mixers (SOMs) are used as receivers in low profile wireless systems. SOMs are generally more compact than current-reuse receivers because in SOMs, oscillator and mixer functions are integrated into a single stage. FIG. 1B illustrates an the structure of an embodiment of a receiver 120 comprising a first portion 122 and a second portion 124, wherein the first portion 122 comprises a low-noise amplifier and the second portion 124 comprises an SOM. FIG. 1C illustrates the structure of an embodiment of a receiver 140 comprising an SOM without a low-noise amplifier.

As those skilled in the art will understand, an SOM may operate with a single active element, usually a transistor, providing a very compact receiver. Receivers comprising SOMs provide good scalability, are power efficient, and are compact. However, SOM receivers like current-reuse receivers have limited performance. To improve the communication performance of systems using SOM receivers, polarization diversity is considered. FIG. 1D illustrates polarization diversity for a system comprising a receiving chip (RX_Chip) 160 comprising a plurality of SOMs, wherein each I-channel and Q-channel of a quadrature amplitude-modulation (QAM) signal are transmitted and received in orthogonal polarizations (for example horizontal and vertical). While the configuration provides systems comprising SOMs to achieve high spectral efficiency, which is required for modulation methods such as QAM, it requires about double the transmitted power. Further, such configurations are application specific and cannot be readily adapted for use in a multi-function system.

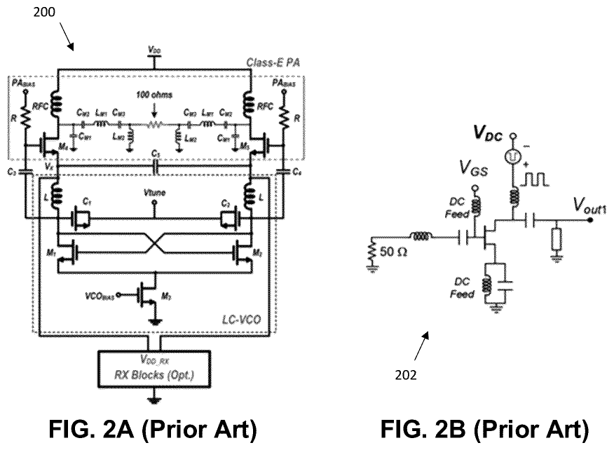

The overall radiation power of large arrays is the sum of compact low power transmitter elements within the array. The emergence of ultra-lower power technologies and wireless area networks has driven a need for power efficient transmitters to extend battery life. Methods and technologies such as subthreshold biasing, low voltage circuits, SOMs, and current-reuse structures are used to address the need for power efficient transmitters. While subthreshold biasing can significantly reduce power dissipation, its use of low frequencies, susceptibility to noise degradation, linear characteristics, and sensitivity to process variations limit its practical use in radio frequency (RF) circuits. A current-reuse transmitter structure 200 is illustrated in FIG. 2A, wherein an oscillator is cascaded with a power amplifier. FIG. 2B illustrates a compact, SOM-based transmitter 202 wherein a power amplifier is not required. Amplitude modulation is commonly implemented using compact transmitters and highly compact low power transmitters providing efficient modulation, such as QAM, is highly desirable for use in multi-function systems.

Embodiments disclosed herein relate to modules, systems and methods for wireless communications using modulated signals, such as with amplitude-shift keying, phase-shift keying and QAM. The present disclosure provides a module that may act as a compact receiver and/or transmitter scalable to millimeter-wave and terahertz frequency bands to operate within a multi-function system.

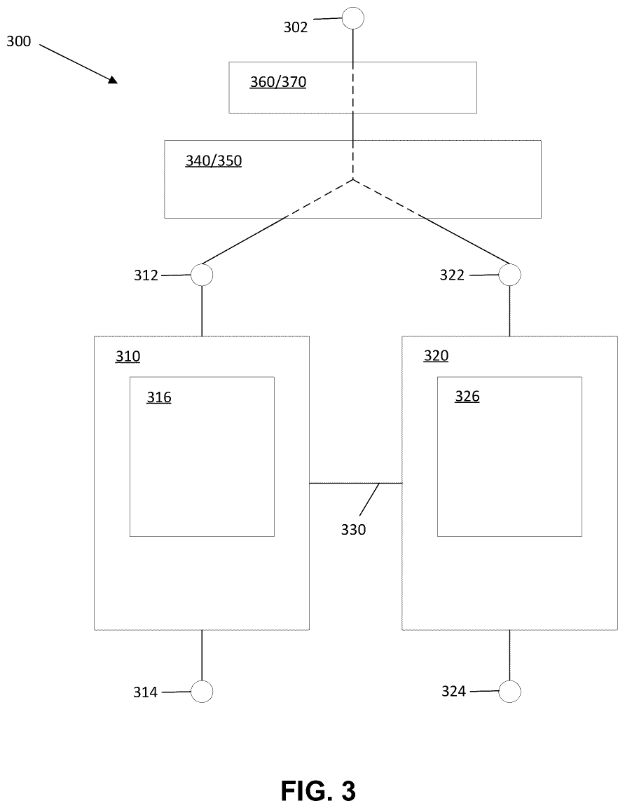

FIG. 3 illustrates a module 300 for modulation and/or demodulation, according to an embodiment of this disclosure. The module 300 comprises a first port 302 for being energized by a first modulated signal, a first SOM 310 and a second SOM 320. The first SOM 310 and the second SOM 320 are for transforming between the first signal and first and second components, respectively, of a second signal. The first SOM 310 comprises a second port 312 and a third port 314. The second SOM 320 comprises a fourth port 322 and a fifth port 324. In embodiments disclosed herein, the first SOM 310 and the second SOM 320 have a substantially same fundamental frequency and are configured to be injection-locked at a coupling frequency through a coupling connection 330. The second port 312 and the fourth port 322 are connected to the first port 302. The third port 314 and the fifth port 324 are configured to be energized by the first and second components of the second signal, respectively.

In embodiments disclosed herein, the coupling frequency is substantially equal to a multiple of the fundamental frequency including a second harmonic frequency of the first and second SOMs 310 and 320. In embodiments disclosed herein, the module 300 is configured for QAM, wherein the coupling frequency is the second harmonic frequency of the first and second SOMs 310 and 320, the first signal is a quadrature amplitude-modulated (QAM) signal, the first component of the second signal is a demodulated in-phase component of the first signal, and the second component of the second signal is a demodulated quadrature component of the first signal. In embodiments disclosed herein, the first signal has a carrier frequency substantially equal to a multiple of the fundamental frequency, including the fundamental frequency or a third harmonic frequency of the first and second SOMs 310 and 320.

In embodiments disclosed herein, the module 300 may be configured to be a receiver, a transmitter, or a transceiver (that is, a combination of a transmitter and a receiver). In embodiments disclosed herein, the first SOM 310 comprises a first passive circuit 316 and the second SOM 320 comprises a second passive circuit 326. The first passive circuit 316 and the second passive circuit 326 may be designed and/or configured for the module 300 to be a receiver, a transmitter, or a transceiver.

In an embodiment disclosed herein, the module 300 is configured as a receiver, wherein the first port 302 is for being energized and receiving the first signal. The first SOM 310 and the second SOM 320 are for demodulating the first signal to the first and second components of the second signal, wherein the third port 314 is for outputting the first component of the second signal the fifth port 324 is for outputting the second component of the second signal. In an embodiment disclosed herein, the module 300 further comprises a power divider 340 for connecting the first port 302 to the second port 312 and the fourth port 322. In an embodiment disclosed herein, the first port 302 is coupled to a low noise amplifier 360 to amplify a received first signal.

In an embodiment disclosed herein, the module 300 is configured as a transmitter, wherein the first port 302 is for being energized and transmitting the first signal. The first SOM 310 and the second SOM 320 are for modulating the second signal to the first signal, wherein the third port 314 is for inputting the first component of the second signal and the fifth port 324 is for inputting the second component of the second signal. In an embodiment disclosed herein, the module 300 further comprises a power combiner 350 for connecting the first port 302 to the second port 312 and the fourth port 322. In an embodiment disclosed herein, the first port 302 is coupled to an amplifier 370 for amplifying the first signal prior to transmission.

In an embodiment disclosed herein, the module 300 is configured as a transceiver, wherein the first passive circuit 316 and the second passive circuit 326 are designed and/or configured for the module 300 to selectively act as a receiver and a transmitter as described above.

The present disclosure provides a module 300 that uses SOMs as compact transmitting and receiving components in a configuration that enhances their overall performance in sensing and communications applications while allowing the SOMs to retain their compact characteristics to permit scalability for millimeter-wave frequency band and higher applications.

In embodiments as described above, the present disclosure is directed at QAM wherein the SOMs are used in a module as a quadrature harmonic self-oscillating mixer (QHSOMs), wherein the coupling frequency is the second harmonic frequency of the first and second SOMs 310, 320, the first signal is quadrature amplitude-modulated, the first component of the second signal is a demodulated in-phase component of the first signal, and the second component of the second signal is a demodulated quadrature component of the first signal. Further, in embodiments disclosed herein, the first signal has a carrier frequency equal to the fundamental frequency or the third harmonic frequency of the first and second SOMs 310, 320. By injection-locking the first SOM 310 and the second SOM 320 at their second harmonic frequency and using the fundamental frequency or the third harmonic frequency as the carrier frequency of the first signal, high isolation between the in-phase component of the first signal (the I-channel) and the quadrature component of the first signal (the Q-channel) is maintained. The high isolation characteristic permits reception and transmission in high efficiency quadrature phase wireless communication modulation schemes (for example, QAM), and adds phase extraction capability, which leads to higher image resolution and sensitivity in imaging and radar applications, respectively.

In an embodiment disclosed herein, the module 300 comprises SOMs and the module 300 is configured as a receiver. The module 300 comprises two substantially identical SOMs, injection-locked together through the coupling connection 330 at their second oscillation harmonic frequency. The first SOM 310 and the second SOM 320 can be injection-locked at different phases including in-phase (0 degrees) or in a differential-phase, such as 180 degrees, at the coupling frequency, being the second harmonic frequency. For QAM, in embodiments disclosed herein, the carrier frequency is any odd-harmonic frequency of the first SOM 310 and the second SOM 320 and the injection-locking occurs in differential-phase, being 180 degrees. In embodiments disclosed herein, the first passive network 316 and the second passive network 326 can be designed and/or configured to provide this functionality.

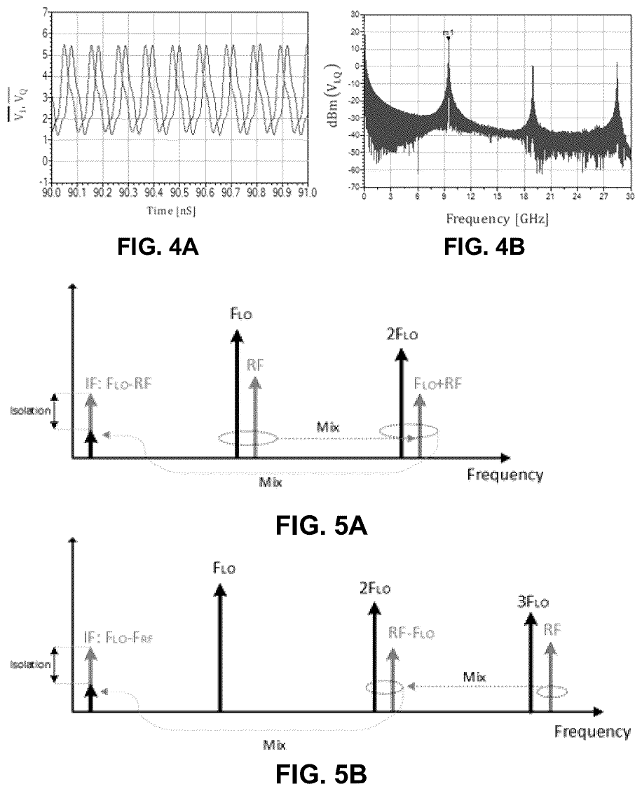

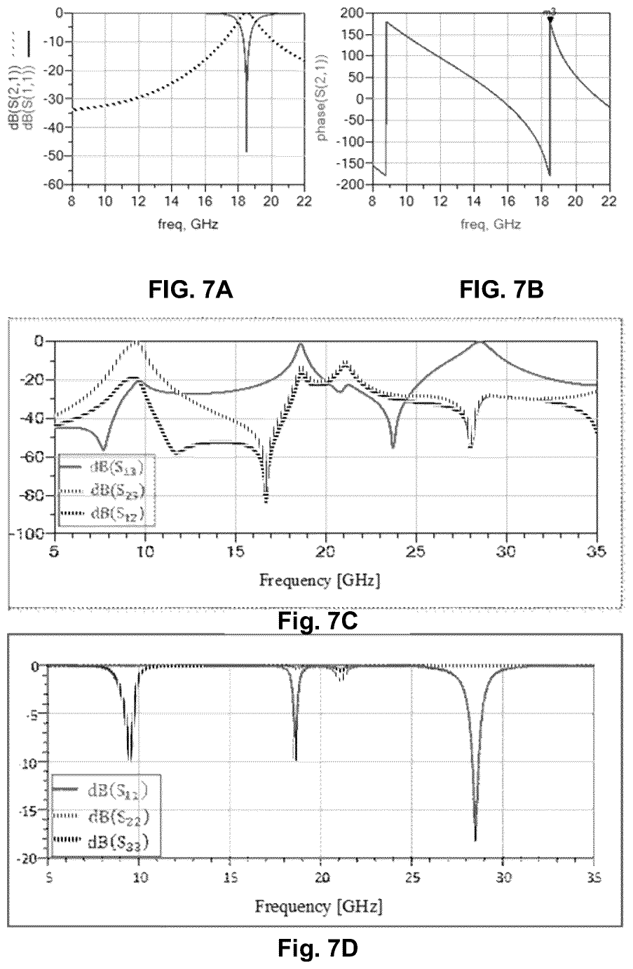

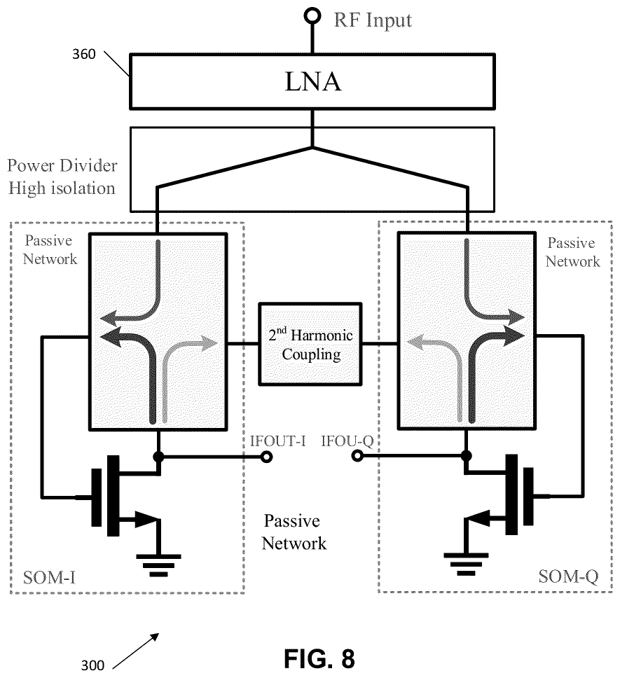

In order to prevent unintended couplings at any harmonic frequencies other than the second harmonic frequency, especially at fundamental harmonic oscillation frequency due to its high power, the coupling connection 330 should act as a band-pass filter centered at second oscillation harmonic frequency. FIG. 7A and FIG. 7B illustrate S-parameters results, representing linear characteristics of RF electronic circuits and components, of the coupling connection 330 illustrated in FIG. 6B, wherein higher than 30 dB isolation at the fundamental frequency (9.5 GHz in this example) is achieved. FIG. 4A and FIG. 4B illustrate time domain and frequency domain, results, respectively, for module 300 or QHSOM configurations described herein. Time domain results illustrated in FIG. 4A show quadrature phase oscillation, and frequency domain results illustrated in FIG. 4B show strong harmonic generation is required for strong super harmonic and harmonic operation (for both transmitting and receiving).

An important characteristic of the embodiment of the module 300 configured for QAM is a high degree of isolation between the I-channel (of the first SOM 310) and the Q-channel (of the second SOM 320). In the topology provided in the present disclosure, unlike loop oscillator and cross-coupled quadrature oscillator topologies, the first SOM 310 and the second SOM 320 are isolated at the fundamental harmonic frequency. At the same time, the first SOM 310 and the second SOM 320 are connected through the coupling connection 330 at the second harmonic frequency. As a result, crosstalk between the first SOM 310 and the second SOM 320 may occur as a result of the coupling connection 330.

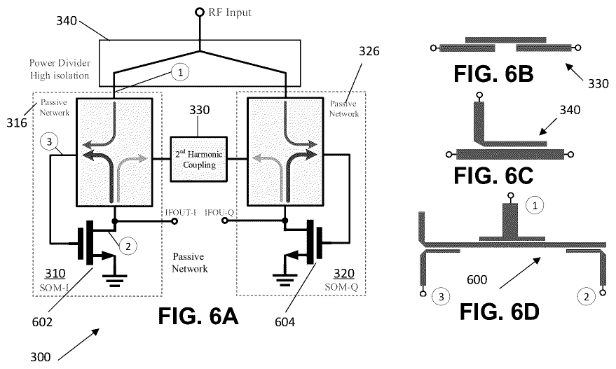

In the present disclosure, we will consider crosstalk in two different scenarios. First, where the first signal comprises a carrier frequency around the fundamental harmonic frequency, and second, where the first signal comprises a carrier frequency around the third harmonic frequency. For this discussion, the path having the highest likelihood of forming crosstalk is considered. FIG. 5A illustrates crosstalk through the coupling connection 330 where the first signal, RF, has a carrier frequency around the fundamental harmonic frequency, F_{LO}, and FIG. 5B illustrates crosstalk through the coupling connection 330 where the first signal, RF, has a carrier frequency around the third harmonic frequency, 3F_{LO}. Referring to FIG. 5A, the input signal is provided at the first port 302 and through to the second port 312, where it is mixed with a local oscillator (LO) of the first SOM 310 at the fundamental harmonic frequency. The resulting up-converted signal passes through the coupling connection 330 through the pass band of the first SOM 310 and the second SOM 320 around the second harmonic frequency, and therefore passes to the second SOM 320. For F_{LO}, the amount of crosstalk is:

$$Crosstalk = CG ( RF , LO ) \times CG ( {F}_{LO} + RF , 2 {F}_{LO} )$$

For 3F_{LO}, the amount of crosstalk is:

$$Crosstalk = CG ( RF , LO ) \times CG ( RF - {F}_{LO} , 2 {F}_{LO} )$$

CG in the above equations is conversion gain in each of the mixing stages within the SOMs. Generally, mixing a signal with a LO produces a strong signal. However, in this case, the second term in each equation relates to the second harmonic frequency and the system can be designed to have high loss and therefore, achieve high isolation.

The high conversion loss in the second term is a result of a tradeoff between harmonic generation and mixing efficiency in the structure provided by the present disclosure. Transistors in the first SOM 310 and the second 320 are harmonic current sources. To obtain high power output at harmonic frequencies in oscillators, a very high load is applied to its output. However, for best mixing efficiency, the output should be short-circuited at a desired harmonic. In embodiments disclosed herein, to obtain a strong connection at the second harmonic frequency, a high-impedance load is applied. This results in very low conversion efficiency at the second harmonic frequency. To enhance mixing performance at the fundamental and third harmonic frequencies, loading should be kept as low as possible for those connections within the first SOM 310 and the second SOM 320.

FIG. 6A illustrates an embodiment of the module 300 or QHSOM operating as a receiver. FIG. 6B illustrates an embodiment of the coupling connection 330. FIG. 6C illustrates an embodiment of the power divider 340. FIG. 6D illustrates an embodiment of a diplexer 600, which guides the first signal towards a gate of a transistor 602, 604 of an SOM 310, 320 for maximum sensitivity and to prevent radiation. Connections for the diplexer are indicated with corresponding labels (1, 2, 3) in FIG. 6A and FIG. 6D. In embodiments disclosed herein, quadrature phase oscillation occurs at all odd harmonics with the coupling connection 330 at the second harmonic frequency as this provides the receiver with desired features. The design of passive circuit elements, including the first passive circuit 316 and the second passive circuit 326, depends on whether operation is at the fundamental harmonic or higher harmonic frequencies.

Operation at the fundamental harmonic frequency provides a strong harmonic component, and therefore, a high conversion or mixing efficiency. In embodiments disclosed herein, design of the power divider 340 is important as it must provide high isolation between the first SOM 310 and the second SOM 320 to ensure that the coupling connection at the second harmonic frequency is the strongest connection between the first SOM 310 and the second SOM 320.

Operation at higher order harmonic frequencies (e.g. 3^{rd}, 5^{th}, etc.) in a harmonic mode allows scaling up the carrier frequency to higher than a cutoff frequency of transistors contained in the module 300. In the harmonic mode, an SOM may comprise a passive diplexer 600. FIG. 7A and FIG. 7B illustrate s-parameters of the embodiment of the coupling connection 330 of FIG. 6B around a second harmonic frequency. FIG. 7C and FIG. 7D illustrate s-parameters of the embodiment of the diplexer 600 of FIG. 6D providing complete path at oscillation frequency (label 2 to label 3) and directing received RF (from label 1) to the gate (label 3). As illustrated, the diplexer 600 guides the first signal at a higher order harmonic frequency to a gate of a transistor 602, 604 within the SOM 310, 320 to get provide high sensitivity and conversion gain, while also providing complete path for fundamental oscillation harmonic between drain and gate to maintain oscillation. This feature is important at millimeter-wave band and higher, as conversion efficiency of harmonic mixing is inherently low.

In the first and second passive circuits 316, 326, no electrical connection between an output of a transistor 602, 604 (drain in a metal-oxide-semiconductor field-effect transistor (MOSFET), or collector in a bipolar junction transistor (BJT)) is preferred as this provides high impedance at the carrier frequency, and therefore provides high gain thereat. Any types of transistors that can provide oscillation and mixing operations can be also be used in QHSOM. Further, while schematics and circuits have been illustrated herein with specific components and layouts, embodiments of the module 300 may be implemented in suitable technologies such as complementary metal-oxide semiconductor (CMOS) with appropriate alterations and variations.

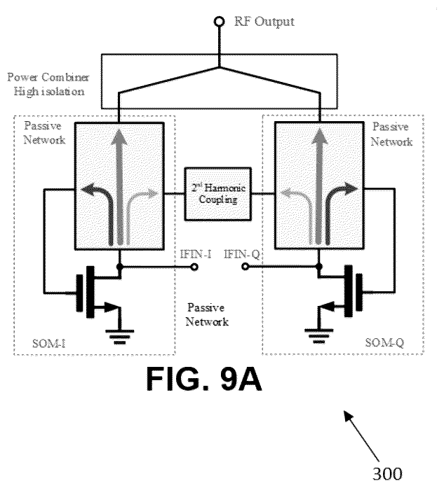

In embodiments disclosed herein, the first port 302 of the module 300 is coupled to a low noise amplifier 360 when used in frequency bands where efficient low noise amplification is possible. This is similar to the structure illustrated in FIG. 1B wherein a low noise amplifier 360 is at a first portion. Referring to FIG. 3 and FIG. 8, the addition of a low noise amplifier 360 does not require alteration to the structure of the remainder of the module 300 or QHSOM. The addition of a low noise amplifier 360 may improve functionality of the module 300 in applications mostly at lower frequency, where transistor efficiency and performance is acceptable with cascoding.

As described above, in embodiments disclosed herein, the module 300 comprises SOMs and the module 300 is configured as a transmitter. The module 300 comprises two substantially identical SOMs, injection-locked together through the coupling connection 330 at their second oscillation harmonic frequency. The first SOM 310 and the second SOM 320 can be injection-locked at different phases includes in-phase (0 degrees) or in a differential-phase, such as 180 degrees, at the coupling frequency, being the second harmonic frequency. For QAM, in embodiments disclosed herein, the carrier frequency is any odd-harmonic frequency of the first SOM 310 and the second SOM 320 and the injection-locking occurs in differential-phase, being 180 degrees. In embodiments disclosed herein, the first passive network 316 and the second passive network 326 can be designed and/or configured to provide this functionality. This allows operation at the fundamental or higher order odd harmonic frequencies (e.g. 3^{rd}, 5^{th}, etc.) as goal harmonics to transmit.

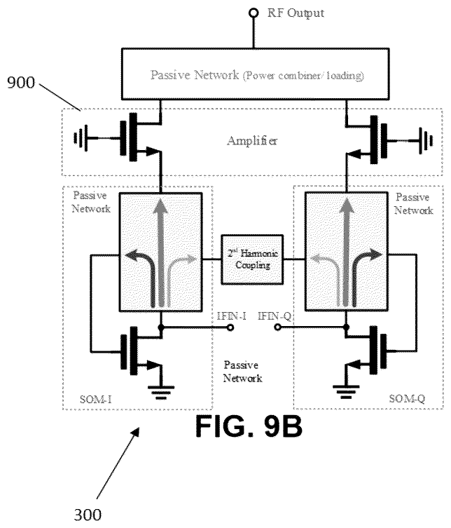

A significant difference between operation of the module 300 as a transmitter and a receiver is the mechanism of mixing. In a receiver, the first signal is a small-RF signal, which is mixed with a LO and its harmonics inside a non-linear element (e.g. a transistor), which normally has a close range of frequencies. In a transmitter, first and second components of the second signal are very low frequency, large amplitude intermediate frequency signals. Applying the first and second components of the second signal, representing the I-channel and Q-channel in QAM applications, to the first SOM 310 and the second SOM 320, and adding the resulting up-converted outputs in the power combiner 350 in a power combiner 350 form a modulated first signal to be transmitted. FIG. 9A illustrates an embodiment of a module 300 or a QHSOM configured as a transmitter.

It is important to note that, despite modulating power supply bias voltage by the second signal, oscillation never dies out. Therefore, the first SOM 310 and the second SOM 320 are oscillating at desired frequencies and injection-locking at the second harmonic frequency is always established. This preserves quadrature phase oscillation, which is a key factor in accurate performance of a QAM system. This is the principle that makes modulating with two injection-locked SOMs possible, without one SOM affecting the other where the connection is established at a harmonic frequency other than the operating harmonic frequency. In comparison, quadrature oscillators like loop oscillator, and cross-coupled oscillator share tank and fundamental oscillation signals, respectively. In those cases, any variation in oscillation amplitude of one oscillator would directly transferred to others and from theory of strongly coupled oscillators, output voltages would vary accordingly. On the other hand, QHSOM with the present disclosure having a connection at the second harmonic frequency, injection signal do not affect operating harmonic frequencies directly indirectly, and does not add up with operating harmonic.

Oscillation frequency can very slightly with a bias voltage value. In worst cases, with two oscillators with maximum voltage difference, we get maximum frequency deviation. As a result, it should be ensured the second harmonic power at the SOM with a lower bias voltage be strong enough preserve injection-locking.

As above, operation at the fundamental harmonic frequency provides a strong harmonic component, and therefore, a high conversion or mixing efficiency. In embodiments disclosed herein, design of the power divider 340 is important as it must provide high isolation between the first SOM 310 and the second SOM 320 to ensure that the coupling connection at the second harmonic frequency is the strongest connection between the first SOM 310 and the second SOM 320.

To increase transmission power and communication range, in embodiments, disclosed herein, it is possible it is possible to integrate an amplifier 370 in an output stage of the module 300. FIG. 9B illustrates an embodiment wherein the module 300 comprises cascoding a stage of amplification 900 to improve output power without affecting modulation and oscillation performances. However, as mentioned for current-reuse topology, cascoding stages is possible only if transistors maintain high efficiency with their provided portion of power supply voltage, which is usually satisfied when operation frequency is far from transistors' cutoff frequency.

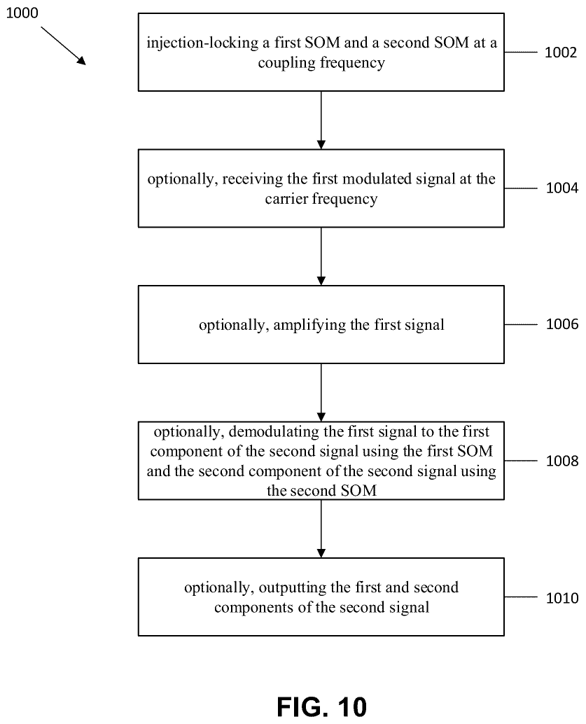

FIG. 10 is a flowchart showing the steps of a method 1000, according to one embodiment of the present disclosure. The method 1000 begins with injection-locking a first SOM and a second SOM at a coupling frequency (step 1002), wherein the first and second SOMs have a substantially same fundamental frequency, the first and second SOMs are oscillating at a carrier frequency, the first SOM is for transforming between a first signal and a first component of the second signal, and the second SOM is for transforming between the first signal and a second component of the second signal. At step 1004, optionally, the method 1000 comprises receiving the first modulated signal at the carrier frequency. At step 1006, optionally, the method 1000 comprises amplifying the first signal. At step 1008, optionally, the method 1000 comprises demodulating the first signal to the first component of the second signal using the first SOM and the second component of the second signal using the second SOM. At step 1010, optionally, the method 1000 comprises outputting the first and second components of the second signal.

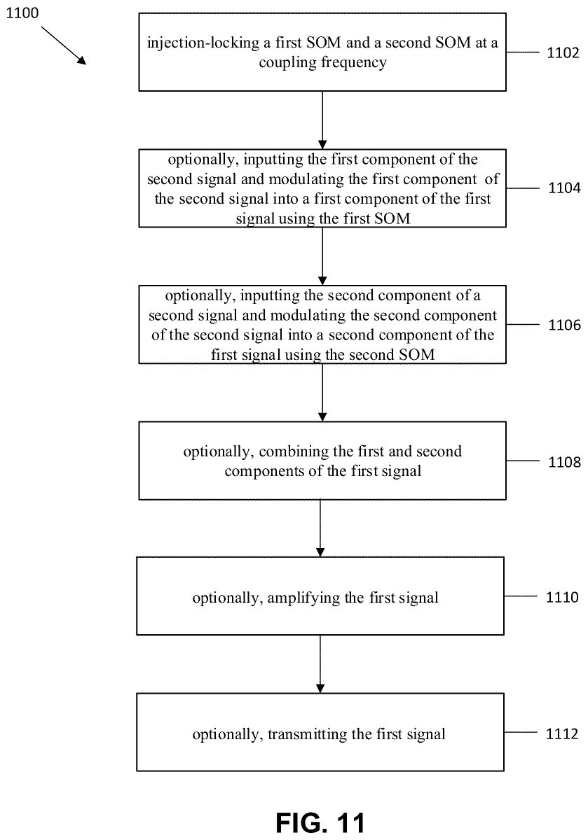

FIG. 11 is a flowchart showing the steps of a method 1100, according to one embodiment of the present disclosure. The method 1100 begins with injection-locking a first SOM and a second SOM at a coupling frequency (step 1102), wherein the first and second SOMs have a substantially same fundamental frequency, the first and second SOMs are oscillating at a carrier frequency, the first SOM is for transforming between a first signal and a first component of the second signal, and the second SOM is for transforming between the first signal and a second component of the second signal. At step 1104, optionally, the method comprises inputting the first component of the second signal and modulating the first component of the second signal into a first component of the first signal using the first SOM. At step 1106, optionally, the method comprises inputting the second component of a second signal and modulating the second component of the second signal into a second component of the first signal using the second SOM. At step 1108, optionally, the method comprises combining the first and second components of the first signal. At step 1110, optionally, the method 1100 comprises amplifying the first signal. At step 1112, optionally, the method comprises transmitting the first signal.

In embodiments disclosed herein, in the methods 1000 and 1100, the coupling frequency is substantially equal to a multiple of the fundamental frequency, including the second harmonic frequency of the first and second SOMs, and the carrier frequency is substantially equal to a multiple of the fundamental frequency including the fundamental and a third harmonic frequency of the first and second SOMs. In embodiments disclosed herein, in methods 1000 and 1100, the second SOM oscillates at about 180 degrees out of phase relative to the first SOM, the first signal is quadrature amplitude-modulated, and the first component of the second signal is a demodulated in-phase component of the first signal and the second component of the second signal is a demodulated quadrature component of the amplitude-modulated signal.

1. A module comprising:
a first port for being energized by a first modulated signal;
a first self-oscillating mixer (SOM) for transformation between the first signal and a first component of a second signal, the first SOM comprising a second port and a third port; and
a second SOM for transformation between the first signal and a second component of the second signal, the second SOM comprising a fourth port and a fifth port;
wherein the first and second SOMs have a substantially same fundamental frequency;
wherein the first and second SOMs are configured to be injection-locked at a coupling frequency;
wherein the second and fourth ports are connected to the first port; and
wherein the third and fifth ports are configured to be energized by the first and second components of the second signal, respectively.

2. The module of claim 1, wherein the coupling frequency is substantially equal to a multiple of the fundamental frequency.

3. The module of claim 1, wherein the coupling frequency is substantially equal to a second harmonic frequency of the first and second SOMs.

4. The module of claim 3, wherein the second SOM is configured to oscillate about 180 degrees out of phase with the first SOM;
wherein the first signal is quadrature amplitude-modulated;
wherein the first component of the second signal is a demodulated in-phase component of the first signal; and
wherein the second component of the second signal is a demodulated quadrature component of the first signal.

5. The module of claim 1, wherein the first signal has a carrier frequency substantially equal to one or more of: a multiple of the fundamental frequency and the fundamental frequency or a third harmonic frequency of the first and second SOMs.

6. The module of claim 1, wherein the first port is for being energized by and receiving the first signal;
wherein the first and second SOMs are for demodulating the first signal to the first and second components of the second signal; and
wherein the third and fifth ports are for outputting the first and second components of the second signal, respectively.

7. The module of claim 6, wherein the first port is connected to the second and fourth ports via a power divider.

8. The module of claim 6, wherein the first port is coupled to a low noise amplifier.

9. The module of claim 1, wherein the first port is for being energized by and transmitting the first signal;
wherein the first and second SOMs are for modulating the second signal to the first signal; and
wherein the third and fifth ports are for inputting the first and second components of the second signal, respectively.

10. The module of claim 9, wherein the first port is connected to the second and fourth ports via a power combiner.

11. The module of claim 9, wherein the first port is coupled to an amplifier.

12. A method comprising:
injection-locking a first self-oscillating mixer (SOM) and a second SOM at a coupling frequency;
wherein the first and second SOMs have a substantially same fundamental frequency;
wherein the first and second SOMs are oscillating at a carrier frequency;
wherein the first SOM is for transforming between a first signal and a first component of a second signal; and
wherein the second SOM is for transforming between the first signal and a second component of the second signal.

13. The method of claim 12, wherein the coupling frequency is substantially equal to a multiple of the fundamental frequency.

14. The method of claim 12, wherein the coupling frequency is substantially equal to a second harmonic frequency of the first and second SOMs.

15. The method of claim 14, wherein the second SOM oscillates at about 180 degrees out of phase relative to the first SOM;
wherein the first signal is quadrature amplitude-modulated; and
wherein the first component of the second signal is a demodulated in-phase component of the first signal and the second component of the second signal is a demodulated quadrature component of the amplitude-modulated signal.

16. The method of claim 12, wherein the carrier frequency is substantially equal to a multiple of the fundamental frequency.

17. The method of claim 12, wherein the carrier frequency is substantially equal to the fundamental frequency or a third harmonic frequency of the first and second SOMs.

18. The method of claim 12, further comprising the steps of:
receiving the first modulated signal at the carrier frequency;
demodulating the first signal to the first component of the second signal using the first SOM and the second component of the second signal using the second SOM; and
outputting the first and second components of the second signal.

19. The method of claim 12, further comprising the steps of:
inputting the first component of the second signal and modulating the first component of the second signal into a first component of the first signal using the first SOM;
inputting the second component of a second signal and modulating the second component of the second signal into a second component of the first signal using the second SOM;
combining the first and second components of the first signal; and
transmitting the first signal.

20. The method of claim 12, further comprising amplifying the first signal.
